(19) United States
(12) Patent Application Publication
(10) Pub. No.: US 2024/0170621 A1
(43) Pub. Date: May 23, 2024

(54) DISPLAY DEVICE

(71) Applicant: Samsung Display Co., LTD., Yongin-si (KR)

(72) Inventor: Ki Bum KIM, Yongin-si (KR)

(21) Appl. No.: 18/505,836

(22) Filed: Nov. 9, 2023

(30) Foreign Application Priority Data
Nov. 23, 2022 (KR) 10-2022-0158615

(51) Int. Cl. H01L 33/52; H01L 25/075; H01L 33/50; H01L 33/62

(52) U.S. Cl. CPC H01L 33/52; H01L 25/0753; H01L 33/50; H01L 33/62

(57) ABSTRACT

A display device may include: a substrate including a display area and a peripheral area; a first inorganic layer disposed on the substrate; a first organic layer disposed on the first inorganic layer; a light emitting element disposed in the display area; a second inorganic layer disposed on the first organic layer and the light emitting element; a second organic layer disposed on the second inorganic layer; a color conversion layer disposed on the second inorganic layer; a third inorganic layer disposed on the second inorganic layer and the color conversion layer; and a first dam structure disposed on the second inorganic layer. The first organic layer may include at least two openings. The second inorganic layer may directly contact the first inorganic layer through the openings. The third inorganic layer may directly contact the second inorganic layer in the openings.

### CROSS-REFERENCE TO RELATED APPLICATION

This application claims priority to and the benefit of Korean patent application number 10-2022-0158615, filed on Nov. 23, 2022, the entire disclosure of which is incorporated by reference herein.

### BACKGROUND

### 1. Field

One or more embodiments of the present disclosure relate to a display device.

### 2. Description of Related Art

Recently, as interest in information display increases, research and development on display devices have been continuously conducted.

### SUMMARY

One or more embodiments of the present disclosure are directed to a display device capable of preventing water from permeating a display area, thus having improved reliability.

However, aspects and features of embodiments of the present disclosure are not limited to the above-described aspects and features, and various modifications are possible without departing from the spirit and scope of the present disclosure.

One or more embodiments of the present disclosure may provide a display device including: a substrate including a display area and a peripheral area located on one side of the display area; a first inorganic layer on the substrate; a first organic layer on the first inorganic layer; a light emitting element on the first organic layer in the display area; a second inorganic layer on the first organic layer and the light emitting element; a second organic layer on the second inorganic layer; a color conversion layer on the second inorganic layer in the display area, and configured to convert a wavelength of light emitted from the light emitting element; a third inorganic layer on the second inorganic layer and the color conversion layer; and a first dam structure on the second inorganic layer in the peripheral area. The first organic layer may include at least two openings between the first dam structure and the display area. The second inorganic layer may directly contact the first inorganic layer through the at least two openings. The third inorganic layer may directly contact the second inorganic layer in the at least two openings.

In one or more embodiments, the display device may further include a transistor on the substrate. The first insulating layer may be on the first transistor.

In one or more embodiments, the display device may further include a second dam structure on the first organic layer in the peripheral area, and located between the first dam structure and the display area.

In one or more embodiments, the at least two openings of the first organic layer may be between the second dam structure and the display area.

In one or more embodiments, the first organic layer between the first dam structure and the second dam structure may not include an opening.

In one or more embodiments, the first organic layer between the first dam structure and the display area may include a first opening and a second opening that is spaced from the first opening.

In one or more embodiments, the first opening and the second opening may be located between the second dam structure and the display area.

In one or more embodiments, the first opening may be between the second dam structure and the display area, and the second opening may be between the first dam structure and the second dam structure.

In one or more embodiments, the first organic layer between the first dam structure and the display area may include a first opening, a second opening, and a third opening that are spaced from each other.

In one or more embodiments, the first opening, the second opening, and the third opening may be between the second dam structure and the display area.

In one or more embodiments, the first opening and the second opening may be between the second dam structure and the display area. The third opening may be between the first dam structure and the second dam structure.

In one or more embodiments, the first organic layer between the first dam structure and the display area may include a first opening, a second opening, a third opening, and a fourth opening that are spaced from each other. The first opening and the second opening may be between the second dam structure and the display area. The third opening and the fourth opening may be between the first dam structure and the second dam structure.

In one or more embodiments, the first organic layer between the first dam structure and the display area may include a first opening, a second opening, a third opening, a fourth opening, and a fifth opening that are spaced from each other. The first opening, the second opening, and the third opening may be between the second dam structure and the display area. The fourth opening and the fifth opening may be between the first dam structure and the second dam structure.

In one or more embodiments, the first organic layer further includes at least one opening between the first dam structure and a perimeter of the display device.

In one or more embodiments, the second organic layer may be on the third organic layer. The display device may further include a fourth inorganic layer on the second organic layer and configured to cover the display area and the peripheral area. The fourth inorganic layer may directly contact the third inorganic layer in the peripheral area.

In one or more embodiments, the display device may further include a first bank on the first organic layer in the display area; and a first bank pattern on the first organic layer in the peripheral area. The first dam structure may be on the first bank pattern. The second insulating layer may cover the first bank and the first bank pattern.

In one or more embodiments, the color conversion layer may further include a second bank overlapping the first bank in a plan view. The first dam structure may be at a same layer as the second bank.

One or more embodiments of the present disclosure may provide a display device including: a substrate including a display area and a peripheral area located on at least one side of the display area; a first inorganic layer on the substrate; a first organic layer on the first inorganic layer; a light emitting element on the first organic layer in the display area; a second inorganic layer on the first organic layer and the light emitting element; and a first dam structure and a second dam structure in the peripheral area. The first organic layer may include at least two openings between the first dam structure and the second dam structure. The second inorganic layer may directly contact the first inorganic layer through the at least two openings.

In one or more embodiments, the first organic layer between the second dam structure and the display area may not include an opening.

In one or more embodiments, the display device may further include a transistor on the substrate. The first insulating layer may be on the transistor.

### BRIEF DESCRIPTION OF THE DRAWINGS

FIG. 1 is a plan view illustrating a display device in accordance with one or more embodiments.

FIG. 2 is a circuit diagram illustrating an embodiment of a pixel included in the display device of FIG. 1.

FIG. 3 is a sectional view illustrating an embodiment of a pixel included in a display area of the display device of FIG. 1.

FIG. 4 is a sectional view illustrating an embodiment of a peripheral area of the display device of FIG. 1.

FIG. 5 is a plan view illustrating an embodiment of a peripheral area of the display device of FIG. 1.

FIG. 6 is an enlarged view illustrating a passivation layer and an inorganic insulating layer that are included in the peripheral area of FIG. 4.

FIG. 7 and FIG. 8 are sectional views illustrating different embodiments of the peripheral area of the display device of FIG. 1.

FIG. 9 to FIG. 13 are sectional views illustrating different embodiments of the peripheral area of the display device of FIG. 1.

FIG. 14 is a sectional view illustrating an embodiment of the peripheral area of the display device of FIG. 3.

FIG. 15 and FIG. 16 are diagrams illustrating a light emitting element in accordance with one or more embodiments.

### DETAILED DESCRIPTION

One or more embodiments of the present disclosure will hereinafter be described in detail with reference to the accompanying drawings. The same reference numerals are used throughout the different drawings to designate the same components, and repetitive description of the same components will be omitted.

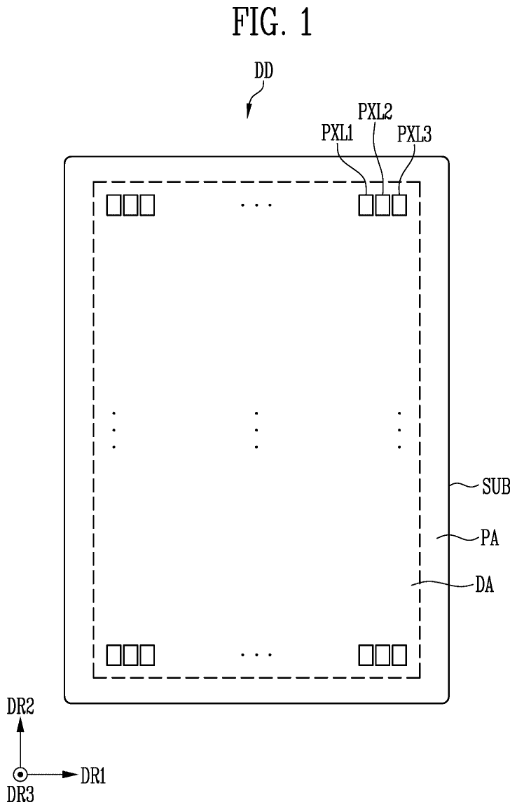

FIG. 1 is a plan view illustrating a display device DD in accordance with one or more embodiments.

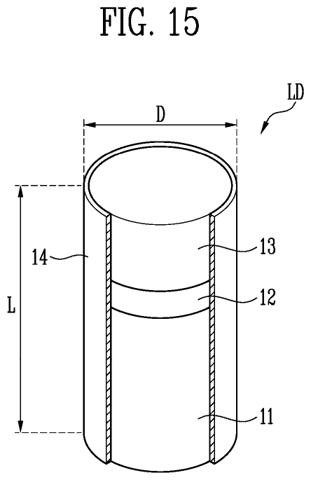

Referring to FIG. 1, the display device DD may include a substrate SUB, pixels PXL1, PXL2, and PXL3 provided on the substrate SUB and each including at least one light emitting element (e.g., a light emitting element LD of FIG. 15), a driver provided on the substrate SUB and configured to drive the pixels PXL1, PXL2, and PXL3, and a line component provided to connect the pixels PXL1, PXL2, and PXL3 with the driver.

The display device DD may have various shapes. For example, the display device DD may be provided in the form of a rectangular plate, but the present disclosure is not limited thereto. For instance, the display device DD may have a shape such as a circular shape or an elliptical shape. Furthermore, the display device DD may have an angled corner and/or curved corner. For convenience of explanation, FIG. 1 illustrates that the display device DD has a rectangular plate shape. In addition, in FIG. 1, an extension direction (e.g., a horizontal direction) of a short side of the display device DD is designated as a first direction DR1, and an extension direction (e.g., a vertical direction) of a long side thereof is designated as a second direction DR2.

The substrate SUB may form a base of the display device DD, and may be a rigid or flexible substrate or film. For example, the substrate SUB may be a rigid substrate made of glass or reinforced glass, a flexible substrate (or a thin film) formed of plastic or metal, or at least one insulating layer. The material and/or properties of the substrate SUB are not particularly limited.

The substrate SUB (or the display device DD) may include a display area DA configured to display an image, and a peripheral area PA (or a non-display area) formed in an area other than the display area DA. The display area DA may form a screen on which an image is displayed. The peripheral area PA may be located on at least one side of the display area DA to be around (e.g., to enclose) the display area DA, but the present disclosure is not limited thereto. The peripheral area PA may enclose the perimeter (or edges) of the display area DA.

The pixel PXL may be disposed in the display area DA on the substrate SUB. The peripheral area PA may be disposed around the display area DA. A structure for protecting components included in the pixel PXL disposed in the display are DA may be provided in the peripheral area PA, but the present disclosure is not limited thereto. The peripheral area PA may be an area in which the driver configured to drive the pixels PXL1, PXL2, and PXL3 and a portion of the line component for connecting the pixels PXL1, PXL2, and PXL3 to the driver are provided. The line component may electrically connect the driver with the pixels PXL1, PXL2, and PXL3. The line component may include a fanout line connected to signal lines, e.g., a scan line, a data line, and an emission control line, which are connected to each of the pixels PXL1, PXL2, and PXL3 to provide signals to each of the pixels PXL1, PXL2, and PXL3.

The pixels PXL1, PXL2, and PXL3 may include a first pixel PXL1, a second pixel PXL2, and a third pixel PXL3. In one or more embodiments, the first pixel PXL1 may be a red pixel, the second pixel PXL2 may be a green pixel, and the third pixel PXL3 may be a blue pixel. However, the present disclosure is not limited to the foregoing. Each of the pixels PXL1, PXL2, and PXL3 may emit light having a color different from red, green, or blue.

Each of the pixels PXL1, PXL2, and PXL3 may include at least one or more light emitting elements LD configured to be driven in response to a corresponding scan signal and a corresponding data signal. The light emitting element LD may have a small size ranging from the nano scale (or the nanometer scale) to the micro scale (the mircrometer scale) and may be connected in parallel to light emitting elements LD disposed adjacent thereto, but the present disclosure is not limited thereto. The light emitting element LD may form a light source of each of the pixels PXL1, PXL2, and PXL3.

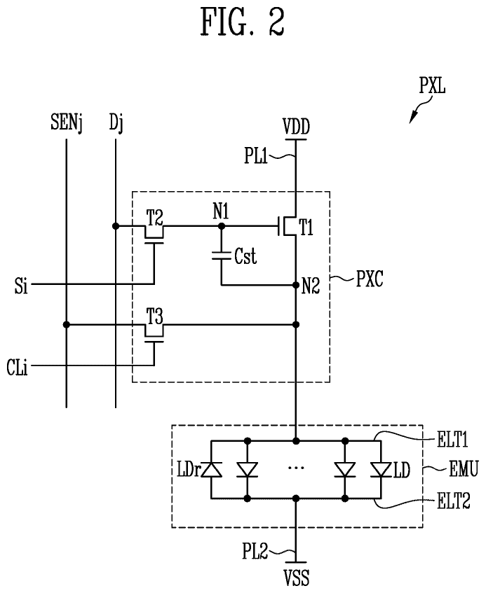

FIG. 2 is a circuit diagram illustrating an embodiment of a pixel included in the display device of FIG. 1.

In the following description, the term “pixel PXL” will be used to collectively designate the first pixel PXL1, the second pixel PXL2, and the third pixel PXL3.

Referring to FIGS. 1 and 2, the pixel PXL may include an emission unit EMU (or an emission layer) configured to generate light having a luminance corresponding to a data signal. Furthermore, the pixel PXL may selectively further include a pixel circuit PXC configured to drive the emission unit EMU.

The emission unit EMU may include a plurality of light emitting elements LD connected in parallel between a first power line PL1 which is connected to a first driving power supply VDD and to which a voltage of the first driving power supply VDD is applied, and a second power line PL2 which is connected to a second driving power supply VSS and to which a voltage of the second driving power supply VSS is applied. For example, the emission unit EMU may include a first pixel electrode ELT1 connected to the first driving power supply VDD via the pixel circuit PXC and the first power line PL1, a second pixel electrode ELT2 connected to the second driving power supply VSS by the second power line PL2, and a plurality of light emitting elements LD connected in parallel to each other in the same direction between the first and second pixel electrodes ELT1 and ELT2. In one or more embodiments, the first pixel electrode ELT1 may be an anode, and the second pixel electrode ELT2 may be a cathode.

Each of the light emitting elements LD included in the emission unit EMU may include one end connected to the first driving power supply VDD through the first pixel electrode ELT1, and a remaining end connected to the second driving power supply VSS through the second pixel electrode ELT2. The first driving power supply VDD and the second driving power supply VSS may have different potentials. For example, the first driving power supply VDD may be set to a high-potential power supply, and the second driving power supply VSS may be set to a low-potential power supply. Here, a difference in potential between the first and second driving power supplies VDD and VSS may be set to a value equal to or greater than a threshold voltage of the light emitting elements LD during an emission period of the pixel PXL.

As described above, the light emitting elements LD that are connected in parallel to each other in the same direction (e.g., in a forward direction) between the first pixel electrode ELT1 and the second pixel electrode ELT2 to which the voltages of the different power supplies are supplied may form respective valid light sources.

In one or more embodiments, the light emitting elements LD of the emission unit EMU may emit light having a luminance corresponding to driving current supplied thereto through the corresponding pixel circuit PXC. For example, during each frame period, driving current corresponding to a grayscale value of corresponding frame data of the pixel circuit PXC may be supplied to the emission unit EMU. The driving current supplied to the emission unit EMU may be divided into parts that flow into the respective light emitting elements LD. Hence, each of the light emitting elements LD may emit light having a luminance corresponding to current applied thereto, so that the emission unit EMU may emit light having a luminance corresponding to the driving current.

Although there has been described the embodiment in which the opposite ends of the light emitting elements LD are connected in the same direction between the first and second driving power supplies VDD and VSS, the present disclosure is not limited thereto. In one or more embodiments, the emission unit EMU may further include at least one invalid light source, e.g., a reverse light emitting element LDr, as well as including the light emitting elements LD that form the respective valid light sources. The reverse light emitting element LDr, along with the light emitting elements LD that form the valid light sources, may be connected in parallel between the first and second electrodes ELT1 and ELT2. Here, the reverse light emitting element LDr may be connected between the first and second electrodes ELT1 and ELT2 in a direction opposite to that of the light emitting elements LD. Even if a driving voltage (e.g., a normal directional driving voltage) is applied between the first and second pixel electrodes ELT1 and ELT2, the reverse light emitting element LDr remains disabled. Hence, current substantially does not flow through the reverse light emitting element LDr.

The pixel circuit PXC may be connected to a scan line Si and a data line Dj of the pixel PXL. The pixel circuit PXC may be connected to a control line CLi and a sensing line SENj of the pixel PXL. For example, in the case in which the pixel PXL is disposed on an i-th row and a j-th column of the display area DA, the pixel circuit PXC of the pixel PXL may be connected to an i-th scan line Si, a j-th data line Dj, an i-th control line CLi, and a j-th sensing line SENj of the display area DA.

The pixel circuit PXC may include first to third transistors T1 to T3, and a storage capacitor Cst.

The first transistor T1 may be a driving transistor configured to control the driving current to be applied to the emission unit EMU and may be connected between the first driving power supply VDD and the emission unit EMU. In detail, a first terminal of the first transistor T1 may be connected (or coupled) to the first driving power supply VDD through the first power line PL1. A second terminal of the first transistor T1 may be connected to a second node N2. A gate electrode of the first transistor T1 may be connected to a first node N1. The first transistor T1 may control, in response to a voltage applied to the first node N1, the amount of driving current to be applied from the first driving power supply VDD to the emission unit EMU through the second node N2. In one or more embodiments, the first terminal of the first transistor T1 may be a drain electrode, and the second terminal of the first transistor T1 may be a source electrode, and the present disclosure is not limited thereto. In one or more embodiments, the first terminal may be a source electrode, and the second terminal may be a drain electrode.

The second transistor T2 may be a switching transistor that selects a pixel PXL in response to a scan signal and activates the pixel PXL, and may be connected between the data line Dj and the first node N1. A first terminal of the second transistor T2 may be connected to the data line Dj. A second terminal of the second transistor T2 may be connected to the first node N1. A gate electrode of the second transistor T2 may be connected to the scan line Si. The first terminal and the second terminal of the second transistor T2 are different terminals, and, for example, if the first terminal is a drain electrode, the second terminal may be a source electrode.

When a scan signal having a gate-on voltage (e.g., a high level voltage) is supplied from the scan line Si, the second transistor T2 may be turned on to electrically connect the data line Dj with the first node N1. The first node N1 may be a point at which the second terminal of the second transistor T2 and the gate electrode of the first transistor T1 are connected to each other. The second transistor T2 may transmit a data signal to the gate electrode of the first transistor T1.

The third transistor T3 may obtain a sensing signal through the sensing line SENj by connecting the first transistor T1 to the sensing line SENj, and detect, using the sensing signal, characteristics of the pixel PXL such as a threshold voltage of the first transistor T1. Information about the characteristics of the pixel PXL may be used to convert image data such that a deviation in characteristic between pixels PXL can be compensated for. A second terminal of the third transistor T3 may be connected to the second terminal of the first transistor T1. A first terminal of the third transistor T3 may be connected to the sensing line SENj. A gate electrode of the third transistor T3 may be connected to the control line CLi. Furthermore, in one or more embodiments, the first terminal of the third transistor T3 may be connected to an initialization power supply. The third transistor T3 may be an initialization transistor configured to initialize the second node N2, and may be turned on when a sensing control signal is supplied thereto from the control line CLi, so that the voltage of the initialization power supply can be transmitted to the second node N2. Hence, a second storage electrode of the storage capacitor Cst connected to the second node N2 may be initialized.

A first storage electrode of the storage capacitor Cst may be connected to the first node N1. A second storage electrode of the storage capacitor Cst may be connected to the second node N2. The storage capacitor Cst may be charged with a data voltage corresponding to a data signal to be supplied to the first node N1 during one frame period. Hence, the storage capacitor Cst may store a voltage corresponding to a difference between a voltage of the gate electrode of the first transistor T1 and a voltage of the second node N2.

Although FIG. 2 illustrates an embodiment in which all of the light emitting elements LD that form the emission unit EMU are connected in parallel to each other, the present disclosure is not limited thereto. In one or more embodiments, the emission unit EMU may include at least one serial set (or stage) including a plurality of light emitting elements LD connected in parallel to each other. In other words, the emission unit EMU may be formed of a series/parallel combination structure.

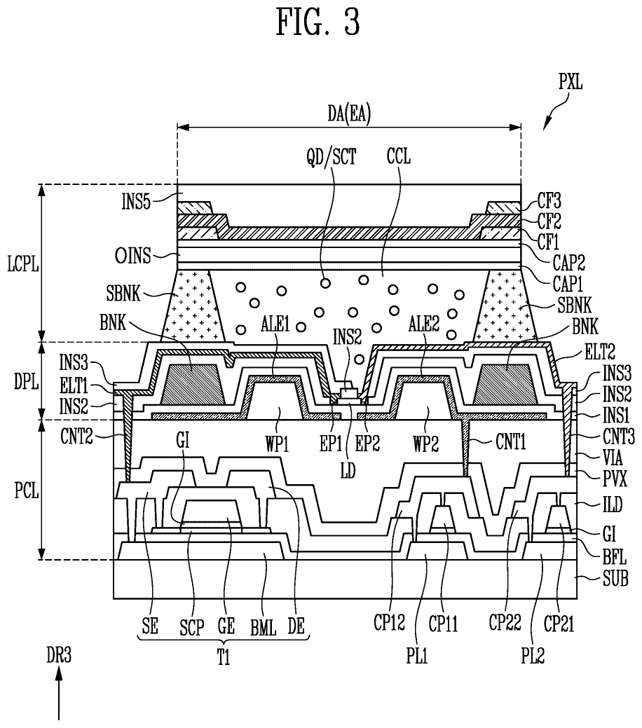

FIG. 3 is a sectional view illustrating an embodiment of a pixel PXL included in a display area of the display device of FIG. 1.

FIG. 3 illustrates a first transistor T1 (e.g., the first transistor T1 of FIG. 2) and the first and second power lines PL1 and PL2, as examples of circuit elements that may be disposed in the pixel circuit layer PCL.

Referring to FIG. 3, the pixel PXL (or the display device) may include a pixel circuit layer PCL, a display element layer DPL, and a light conversion layer LCPL that are disposed on the substrate SUB.

The pixel circuit layer PCL may include the first transistor T1, the first power line PL1, the second power line PL2, and a plurality of insulating layers BFL, GI, ILD, PVX, and VIA. The first transistor T1 may include a bottom metal layer BML, a semiconductor pattern SCP, a gate electrode GE, a source electrode SE (or a second transistor electrode, or a second terminal), and a drain electrode DE (or a first transistor electrode, or a first terminal).

A first conductive layer may be located between the substrate SUB and the buffer layer BFL. The first conductive layer may include a conductive material. The conductive material may include at least one selected from among various metal materials including silver (Ag), magnesium (Mg), aluminum (Al), platinum (Pt), palladium (Pd), gold (Au), nickel (Ni), neodymium (Nd), iridium (Ir), chrome (Cr), titanium (Ti), molybdenum (Mo), copper (Cu), etc., and/or an alloy thereof. The first conductive layer may have a single-layer structure, a double-layer structure, or a multilayer structure.

The first conductive layer may include the bottom metal layer BML, the first power line PL1, and the second power line PL2. The bottom metal layer BML and the gate electrode GE of the first transistor T1 may overlap each other with the buffer layer BFL interposed therebetween in a third direction (e.g., a thickness direction of the substrate SUB). The bottom metal layer BML may be disposed under the semiconductor pattern SCP of the first transistor T1. Here, the bottom metal layer BML may function as a light shielding pattern to stabilize operating characteristics of the first transistor T1.

In one or more embodiments, the first transistor T1 may not include the bottom metal layer BML. In this case, the buffer layer BFL may be directly disposed on the substrate SUB. Furthermore, the bottom metal layer BML may be physically and/or electrically connected with the source electrode SE of the first transistor T1, which will be described below, through a contact hole of an insulating layer. Hence, the threshold voltage of the first transistor T1 may be shifted in a negative direction or a positive direction.

The buffer layer BFL (or a first insulating layer) may cover the first conductive layer, and may be located on the substrate SUB.

The buffer layer BFL may prevent impurities from diffusing into the pixel circuit layer PCL. The buffer layer BFL may include an inorganic insulating material. For example, the inorganic insulating material may include at least one selected from among silicon nitride (SiNₓ), silicon oxide (SiOₓ), silicon oxynitride (SiOₓN_{y}), and/or metal oxide such as aluminum oxide (AlOₓ). The buffer layer BFL may be omitted depending on the material of the substrate SUB or processing conditions.

The semiconductor pattern SCP may be located on the buffer layer BFL. The semiconductor pattern SCP may include a first area (e.g., a source area) connected to the source electrode SE, a second area (e.g., a drain area) connected to the drain electrode DE, and a channel area formed between the first and second areas. The channel area may overlap the gate electrode GE of the first transistor T1 in the third direction DR3. The semiconductor pattern SCP may be a semiconductor pattern formed of polycrystalline silicon, amorphous silicon, an oxide semiconductor, etc.

A gate insulating layer GI (or a second insulating layer) may be disposed on the semiconductor pattern SCP. The gate insulating layer GI may be partially disposed on only the semiconductor pattern SCP, or may be disposed on an overall surface of the substrate SUB. The gate insulating layer GI may include an inorganic material. However, the present disclosure is not limited to the foregoing, and the gate insulating layer GI may include an organic material. For example, the organic layer may include, for example, at least one selected from among polyacrylate resin, epoxy resin, phenolic resin, polyamide resin, polyimide rein, unsaturated polyester resin, poly-phenylen ether resin, poly-phenylene sulfide resin, and/or benzocyclobutene resin.

A second conductive layer may be disposed on the gate insulating layer GI. The second conductive layer may include a conductive material in a manner similar to that of the first conductive layer. The second conductive layer include a gate electrode GE, an 11-th connection pattern CP11, and a 21-st connection pattern CP21.

The gate electrode GE may be disposed on the gate insulating layer GI to overlap the channel area of the semiconductor pattern SCP in the third direction DR3. The 11-th connection pattern CP11 may overlap the first power line PL1 in the third direction DR3. The 21-st connection pattern CP21 may overlap the second power line PL2 in the third direction DR3.

An interlayer insulating layer ILD (or a first interlayer insulating layer, or a third insulating layer) may cover the second conductive layer, and may be disposed on an overall surface of the substrate SUB. The interlayer insulating layer ILD may include an inorganic material in a manner similar to that of the gate insulating layer GI. The interlayer insulating layer ILD may include an organic material.

A third conductive layer may be disposed on the interlayer insulating layer ILD. The third conductive layer may include a conductive material in a manner similar to that of the first conductive layer. The third conductive layer may include a source electrode SE, a drain electrode DE, a 12-th connection pattern CP12, and a 22-nd connection pattern CP22.

The source electrode SE may be brought into contact with or connected to the first area of the semiconductor pattern SCP through a contact hole passing through the interlayer insulating layer ILD, and may be brought into contact with or connected to the bottom metal layer BML through a contact hole passing through the interlayer insulating layer ILD and the buffer layer BFL. The drain electrode DE may be brought into contact with or connected to the second area of the semiconductor pattern SCP through a contact hole passing through the interlayer insulating layer ILD. In a manner similar to the source electrode SE, the 12-th connection pattern CP12 may be brought into contact with or connected to the first power line PL1 and the 11-th connection pattern CP11, and the 22-nd connection pattern CP22 may be brought into contact with or connected to the second power line PL2 and the 21-st connection pattern CP21. For example, the 12-th connection pattern CP12 may be brought into contact with or connected to the first power line PL1 via a contact hole passing through the interlayer insulating layer ILD and the buffer layer BFL and may be brought into contact with or connected to the 11-th connection pattern CP11 through a contact hole passing through the interlayer insulating layer ILD. For example, the 22-nd connection pattern CP22 may be brought into contact with or connected to the second power line PL2 via a contact hole passing through the interlayer insulating layer ILD and the buffer layer BFL and the 21-st connection pattern CP21 through a contact hole passing through the interlayer insulating layer ILD. The 11-th connection pattern CP11 and the 12-th connection pattern CP12 may be connected to the first power line PL1 so that resistance of the first power line PL1 can be reduced. Likewise, the 21-st connection pattern CP21 and the 22-nd connection pattern CP22 may be connected to the second power line PL2 so that resistance of the second power line PL2 can be reduced.

A passivation layer PVX (or a second interlayer insulating layer, or a first inorganic layer) may be disposed on the overall surface of the substrate SUB to cover the third conductive layer. The passivation layer PVX may include an inorganic material. The passivation layer PVX may be provided in a single-layer structure, or may be provided in a multilayer structure having two or more layers. In one or more embodiments, the passivation layer PVX may be omitted. The via layer VIA (e.g., a first organic layer) may include an organic material and may be provided on the overall surface of the substrate SUB to cover the passivation layer PVX. The via layer VIA may provide a planar surface to the top. The passivation layer PVX may protect the first transistor T1 and the 11-th, 12-th, 21-st, and 22-nd connection patterns CP11, CP12, CP21, and CP22 that are disposed under the passivation layer PVX.

The display element layer DPL may be located on the via layer VIA.

The display element layer DPL may include first and second wall patterns WP1 and WP2, first and second alignment electrodes ALE1 and ALE2 (or alignment electrodes, or reflective electrodes), a bank BNK, a light emitting element LD, first and second pixel electrodes ELT1 and ELT2 (or contact electrodes), and a plurality of insulating layers INS1 to INS3.

The first and second wall patterns WP1 and WP2 may be disposed on the via layer VIA.

Each of the first and second wall patterns WP1 and WP2 may have a trapezoidal cross-sectional shape that is reduced in width from one surface (e.g., an upper surface) of the via layer VIA upward in the third direction DR3. In one or more embodiments, each of the first and second wall patterns WP1 and WP2 may include a curved surface having a cross-sectional shape such as a semi-elliptical shape or a semi-circular shape (or a hemispherical shape) that is reduced in width from one surface of the via layer VIA upward in the third direction DR3. In a cross-sectional view, the shape of each of the first and second wall patterns WP1 and WP2 is not limited to the foregoing examples, and may be changed in various ways within a range in which the efficiency of light emitted from each of the light emitting elements LD can be enhanced.

Each of the first and second wall patterns WP1 and WP2 may include an inorganic material or an organic material, and may have a single-layer structure or a multilayer structure. In one or more embodiments, the first and second wall patterns WP1 and WP2 may be omitted. For example, a structure corresponding to the first and second wall patterns WP1 and WP2 may be formed in the via layer VIA.

The first and second electrodes ALE1 and ALE2 may be disposed on the via layer VIA and the first and second wall patterns WP1 and WP2.

The first electrode ALE1 may be disposed on the first wall pattern WP1. The second electrode ALE2 may be disposed on the second wall pattern WP2. In a cross-sectional view, the first and second electrodes ALE1 and ALE2 may respectively have surface profiles corresponding to the shapes of the first and second wall patterns WP1 and WP2.

The first and second electrodes ALE1 and ALE2 each may include a conductive material having a certain reflectivity to enable light emitted from the light emitting element LD to travel in an image display direction (e.g., in the third direction DR3) of the display device. Each of the first and second electrodes ALE1 and ALE2 may have a single-layer structure or a multilayer structure.

The second electrode ALE2 (or the first electrode ALE1) may be brought into contact with or connected to the 12-th connection pattern CP12 through a first contact hole CNT1 passing through the via layer VIA and the passivation layer PVX. The second electrode ALE2 (or the first electrode ALE1) may be electrically connected to the first power line PL1. The second electrode ALE2 may be directly connected to the 12-th connection pattern CP12, but is not limited thereto. For example, in one or more embodiments, the second electrode ALE2 may be connected to the 12-th connection pattern CP12 (or the 11-th connection pattern CP11, or the first power line PL1) through a bridge electrode.

The first and second electrodes ALE1 and ALE2 may be used as alignment electrodes for aligning the light emitting elements LD during a process of fabricating the display device.

The first insulating layer INS1 may be disposed on the via layer VIA to cover at least portions of the first and second electrodes ALE1 and ALE2. The first insulating layer INS1 may be disposed between the first electrode ALE1 and the second electrode ALE2, thus preventing a short circuit from occurring between the first electrode ALE1 and the second electrode ALE2. The first insulating layer INS1 may include an organic material or an inorganic material.

The light emitting element LD may be disposed on the first insulating layer INS1. The light emitting element LD may be aligned between the first electrode ALE1 and the second electrode ALE2 such that a first end EP1 of the light emitting element LD faces the first electrode ALE1, and a second end EP2 thereof faces the second electrode ALE2.

The first end EP1 of the light emitting element LD may partially overlap the first electrode ALE1 in the third direction DR3. The second end EP2 of the light emitting element LD may partially overlap the second electrode ALE2 in the third direction DR3. The present disclosure is not limited thereto.

The bank BNK may be disposed on the first insulating layer INS1. The bank BNK may form a dam structure configured to prevent a solution including the light emitting element LD from being drawn into an adjacent pixel PXL at the step of supplying the light emitting element LD onto the first insulating layer INS1, or to control the amount of solution such that a constant amount of solution is supplied to each pixel PXL. Furthermore, the bank BNK may define an emission area EA.

The bank BNK may include an organic material. In one or more embodiments, the bank BNK may include a light shielding material and/or reflective material. In this case, the bank BNK may prevent a light leakage defect in which light (or rays) leaks between the pixel PXL and a pixel adjacent thereto. For example, the bank BNK may include a color filter material or a black matrix material. Alternatively, in order to enhance the efficiency of light emitted out of the pixel PXL, a separate reflective material layer may be provided and/or formed on the bank BNK.

A second insulating layer INS2 (or a second insulating pattern) may be disposed on the light emitting element LD. The second insulating layer INS2 may be disposed on a portion of the upper surface of the light emitting element LD such that the first end EP1 and the second end EP2 of the light emitting element LD are exposed to the outside. In one or more embodiments, the second insulating layer INS2 may also be disposed on the first insulating layer INS1 and the bank BNK.

The second insulating layer INS2 may include an inorganic material or an organic material, depending on design conditions or the like of the display device including the light emitting element LD. After the alignment of the light emitting element LD on the first insulating layer INS1 has been completed, the second insulating layer INS2 is located on the light emitting element LD so that the light emitting element LD may be prevented from being removed from the aligned position. In the case where a gap (or space) is present between the first insulating layer INS1 and the light emitting element LD before the formation of the second insulating layer INS2, the gap may be filled with the second insulating layer INS2 during a process of forming the second insulating layer INS2.

The first pixel electrode ELT1 may be disposed on the first electrode ALE1. The first pixel electrode ELT1 may directly contact the first end EP1 of the light emitting element LD. The first pixel electrode ELT1 may be brought into contact with or connected to the source electrode SE of the first transistor T1 through a second contact hole CNT2 passing through the second insulating layer INS2, the first insulating layer INS1, the via layer VIA, and the passivation layer PVX. In other words, the first pixel electrode ELT1 may electrically connect the first end EP1 of the light emitting element LD with the source electrode SE of the first transistor T1.

The first pixel electrode ELT1 and the second pixel electrode ELT2 may include a transparent conductive material such as indium tin oxide (ITO), indium zinc oxide (IZO), zinc oxide (ZnOₓ), and/or indium gallium zinc oxide (IGZO).

The third insulating layer INS3 may be disposed on the second insulating layer INS2 and the first pixel electrode ELT1 to cover the second insulating layer INS2 and the first pixel electrode ELT1. The third insulating layer INS3 may be disposed such that a perimeter thereof comes into contact with one end of the second insulating layer INS2 so that the second end EP2 of the light emitting element LD is exposed. The third insulating layer INS3 may include an inorganic material.

The second pixel electrode ELT2 may be disposed on the second electrode ALE2. The second pixel electrode ELT2 may directly contact the second end EP2 of the light emitting element LD. The second pixel electrode ELT2 may be brought into contact with or connected to the 22-nd connection pattern CP22 through a third contact hole CNT3 passing through the third insulating layer INS3, the second insulating layer INS2, the first insulating layer INS1, the via layer VIA, and the passivation layer PVX. In other words, the second pixel electrode ELT2 may electrically connect the second end EP2 of the light emitting element LD with the second power line PL2.

The transparent conductive material (e.g., ITO) may have excellent bonding force with a conductive layer (e.g., the source electrode SE or the 22-nd connection pattern CP22) in the pixel circuit layer PCL, and low contact resistance, compared to the conductive material (or the metal material) having the certain reflectivity. Therefore, the first and second pixel electrodes ELT1 and ELT2 may be directly connected to a component in the pixel circuit layer PCL without passing through the first and second electrodes ALE1 and ALE2. The present disclosure is not limited to the foregoing.

Although in FIG. 3 there has been described that the first pixel electrode ELT1 and the second pixel electrode ELT2 are disposed on different layers with the third insulating layer INS3 interposed therebetween, the present disclosure is not limited thereto. For example, the first pixel electrode ELT1 and the second pixel electrode ELT2 may be disposed on (or at) the same layer (e.g., the second insulating layer INS2) through the same process.

The light conversion layer LCPL may be disposed on the display element layer DPL.

The light conversion layer LCPL may further include a separation bank SBNK, a light conversion layer CCL, and color filters CF1 to CF3.

The separation bank SBNK (or a second bank) may be disposed on the display element layer DPL on the third insulating layer INS3. The separation bank SBNK may be a structure configured to define a location at which the color conversion layer CCL is to be supplied.

The separation bank SBNK may include an organic material. In one or more embodiments, the separation bank SBNK may include a light shielding material. For example, the separation bank SBNK may be a black matrix. In one or more embodiments, the separation bank SBNK may include at least one light shielding material and/or a reflective material, and allow light emitted from the color conversion layer CCL to more reliably travel in the image display direction (or the third direction DR3) of the display device, thus enhancing the light output efficiency of color conversion layer CCL.

The color conversion layer CCL may be disposed on the display element layer DPL (or the light emitting element LD) in an area enclosed by the separation bank SBNK.

The color conversion layer CCL may include color conversion particles QD (or wavelength conversion particles) corresponding to a specific color. For example, the color conversion layer CCL may include color conversion particles QD configured to convert a first color of light (or light in a first wavelength band) that is incident thereon from the light emitting element LD to a second color of light (or a specific color of light, or light in a second wavelength band) and then emit the converted light.

In the case in which the pixel PXL is a red pixel (or a red sub-pixel), the color conversion particles QD of the pixel PXL may include color conversion particles formed of red quantum dots that convert the first color of light emitted from the light emitting element LD to a second color of light (e.g., red light).

In the case in which the pixel PXL is a green pixel (or a green sub-pixel), the color conversion particles QD of the pixel PXL may include color conversion particles formed of green quantum dots that convert the first color of light emitted from the light emitting element LD to a second color of light (e.g., green light).

In the case in which the pixel PXL is a blue pixel (or a blue sub-pixel), the color conversion particles QD of the pixel PXL may include color conversion particles formed of blue quantum dots that convert the first color of light emitted from the light emitting element LD to the second color of light (e.g., blue light). In the case where the pixel PXL is a blue pixel and the light emitting element LD emits blue-based light, the pixel PXL may include a light scattering layer including light scattering particles SCT. The light scattering layer may be omitted depending on the embodiment. In one or more embodiments, in the case where the pixel PXL is a blue pixel, a transparent polymer may be provided in lieu of the color conversion layer CCL.

An organic insulating layer OINS may be disposed on the color conversion layer CCL and the separation bank SBNK.

The organic insulating layer OINS (or a second organic layer) may be provided on the overall surface of the substrate SUB to cover the separation bank SBNK and the color conversion layer CCL. The organic insulating layer OINS may include an an organic material. In one or more embodiments, the organic insulating layer OINS may use a difference in refractive index between the organic insulating layer OINS and adjacent components to totally (or substantially totally) reflect light emitted from the color conversion layer CCL (e.g., light that travels in a diagonal direction), thus enhancing the light output efficiency of the pixel PXL. To achieve the foregoing purpose, the organic insulating layer OINS may have a relatively low refractive index, compared to that of the color conversion layer CCL.

In one or more embodiments, the organic insulating layer OINS may mitigate a step difference formed by components disposed thereunder and have a planar surface.

In one or more embodiments, first and second capping layers CAP1 and CAP2 may be disposed over and under the organic insulating layer OINS.

The first capping layer CAP1 (or a third inorganic layer) may be disposed on the color conversion layer CCL and the separation bank SBNK, and may prevent water (or a solution to be used during a subsequent process) from permeating the color conversion layer CCL disposed thereunder. The first capping layer CAP1 may include an inorganic material.

The second capping layer CAP2 (or a fourth inorganic layer) may be disposed on the organic insulating layer OINS, and may include an inorganic material. The second capping layer CAP2 may prevent water from permeating the organic insulating layer OINS. In one or more embodiments, the second capping layer CAP2 may enhance the bonding force between the organic insulating layer OINS and the color filters.

The color filters CF1, CF2, and CF3 may be disposed on the organic insulating layer OINS.

A color filter layer may include a first color filter CF1, a second color filter CF2, and a third color filter CF3. The first, second, and third color filters CF1, CF2, and CF3 each may include a color filter material that allows a specific color of light converted by the color conversion layer CCL to selectively pass therethrough. For example, the first color filter CF1 may be a red color filter. The second color filter CF2 may be a green color filter. The third color filter CF3 may be a blue color filter. Although FIG. 3 illustrates that the second color filter CF2 is disposed on the color conversion layer CCL of the pixel PXL, the first color filter CF1 may be disposed on the color conversion layer CCL in the case where the pixel PXL is a red pixel. In the case where the pixel PXL is a blue pixel, the third color filter CF3 may be disposed.

The first, second, and third color filters CF1, CF2, and CF3 may overlap each other on the separation bank SBNK, thus preventing optical interference between adjacent sub-pixels from occurring. In one or more embodiments, a separate light shielding pattern may be disposed in the non-emission area NEA, in lieu of a stacked structure formed of the first, second, and third color filters CF1, CF2, and CF3.

A fifth insulating layer INS5 may be disposed on the color filter layer. The fifth insulating layer INS5 may include an inorganic material and/or an organic material. The fifth insulating layer INS5 may cover the entirety of components disposed thereunder and prevent external water or moisture from being drawn into the color filter layer and the display element layer DPL. In one or more embodiments, the fifth insulating layer INS5 may have a multilayer structure. For example, the fifth insulating layer INS5 may be formed of at least two inorganic layers, and at least one organic layer interposed between the at least two inorganic layers. Here, the constituent material and/or structure of the fifth insulating layer INS5 may be changed in various ways. In one or more embodiments, at least one overcoat layer, at least one filler layer, at least one upper substrate, and/or the like may be further disposed over the fifth insulating layer INS5.

Although in the foregoing embodiment the color conversion layer CCL has been described as being directly formed on the display element layer DPL, the present disclosure is not limited thereto. In one or more embodiments, the color conversion layer CCL may be formed on a separate substrate, and then coupled to the display element layer DPL by an adhesive material. For example, the adhesive material may form an optically clear adhesive layer, but is not limited thereto.

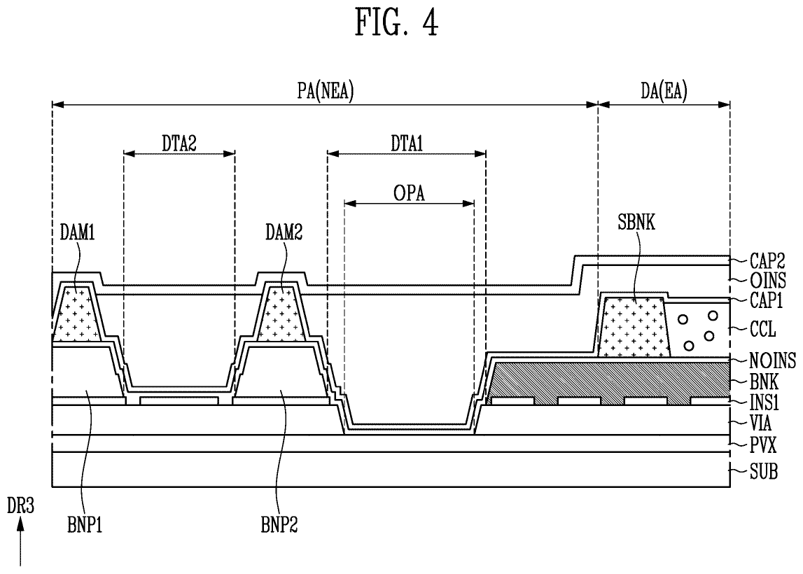

FIG. 4 is a sectional view illustrating an embodiment of the peripheral area PA of the display device DD of FIG. 1.

Referring to FIGS. 1 and 4, FIG. 4 is a sectional view taken along the line extending from the display area DA of the display device DD to an edge of the display device DD, and a left side of the sectional view may be a portion adjacent to the edge of the display area DD.

Referring to FIGS. 3 and 4, some components disposed in the display area DA may extend to the peripheral area PA and may be disposed in the peripheral area PA. For example, the peripheral area PA may include the passivation layer PVX and the via area VIA that are included in the pixel circuit layer PCL of the display area DA. The peripheral area PA may include the organic insulating layer OINS and the first and second capping layers CAP1 and CAP2 that are included in the light conversion layer LCPL of the display area DA. The peripheral area PA may further include first and second bank patterns BNP1 and BNP2, and first and second dam structures DAM1 and DAM2.

The passivation layer PVX (or the first inorganic layer) and the via layer VIA (or the first organic layer) may be successively disposed on the substrate SUB in the third direction DR3. Although FIG. 4 illustrates that the passivation layer PVX is directly disposed on the substrate SUB, a plurality of insulating layers (e.g., at least one of a plurality of insulating layers BFL, ILD, and GI of FIG. 3) may be disposed between the substrate SUB and the passivation layer PVX.

The first insulating layer INS1 may be disposed on the via layer VIA. The first insulating layer INS1 may be disposed on the via layer VIA after at least one area has been removed from the first insulating layer INS1. Because the first insulating layer INS1 is disposed on the via layer VIA after the at least one area thereof has been removed, a come-off phenomenon of the first insulating layer INS1 may be mitigated.

The bank BNK may be disposed on the via layer VIA. The bank BNK may extend from the display area DA and may be disposed in even a portion of the peripheral area PA.

The first and second bank patterns BNP1 and BNP2 may be disposed on the via layer VIA that is disposed in the peripheral area PA. The first and second bank patterns BNP1 and BNP2 may be disposed to be spaced from the bank BNK by a certain distance. In one or more embodiments, the first bank pattern BNP1 may be disposed at a position spaced from the bank BNK by a larger distance than is the second bank pattern BNP2. In other words, the second bank pattern BNP2 may be disposed between the first bank pattern BNP1 and the bank BNK.

Each of the first and second bank patterns BNP1 and BNP2 may have a trapezoidal cross-sectional shape that is reduced in width from one surface (e.g., an upper surface) of the via layer VIA upward in the third direction DR3. In one or more embodiments, each of the first and second bank patterns BNP1 and BNP2 may include a curved surface having a cross-sectional shape such as a semi-elliptical shape or a semi-circular shape (or a hemispherical shape) that is reduced in width from one surface of the via layer VIA upward in the third direction DR3. In a cross-sectional view, the shape of each of the first and second bank patterns BNP1 and BNP2 is not limited to the foregoing embodiments, and may be changed in various ways so long as the organic insulating layer OINS can be prevented from overflowing into the peripheral area PA spaced from the display area DA by a certain distance. Each of the first and second bank patterns BNP1 and BNP2 may include an inorganic material and/or an organic material, and may have a single-layer structure or a multilayer structure. The first dam structure DAM1 may be disposed on the first bank pattern BNP1. The second dam structure DAM2 may be disposed on the second bank pattern BNP2. In one or more embodiments, the first and second bank patterns BNP1 and BNP2 may be omitted. In this case, the first and second dam structures DAM1 and DAM2 may be disposed on the via layer VIA. An inorganic insulating layer NOINS along with the first capping layer CAP1 may be disposed on the first and second dam structures DAM1 and DAM2.

A first depressed area DTA1 (or a trench area) may be disposed between the second bank pattern BNP2 and the bank BNK so that the organic insulating layer OINS can be located in the first depressed area DTA1.

A second depressed area DTA2 may be disposed between the first bank pattern BNP1 and the second bank pattern BNP2 so that the organic insulating layer OINS can be located in the second depressed area DTA2.

The via layer VIA that is disposed in the peripheral area PA may include an opening OPA. The opening OPA may be formed in the via layer VIA at a position adjacent to the display area DA. In one or more embodiments, the opening OPA may be formed between the second dam structure DAM2 and the bank BNK.

The inorganic insulating layer NOINS (or a second inorganic layer) may be disposed on the via layer VIA to cover the first and second bank patterns BNP1 and BNP2 and the bank BNK. The inorganic insulating layer NOINS may be directly adjacent to (e.g., touching or contacting) the passivation layer PVX through the opening OPA. The inorganic insulating layer NOINS may overlap the via layer VIA in the second depressed area DTA2.

The inorganic insulating layer NOINS may be a third insulating layer (e.g., the third insulating layer INS3). In one or more embodiments, the inorganic insulating layer NOINS may be a second insulating layer (e.g., the second insulating layer INS2 of FIG. 3), or may be an insulating layer formed by bonding the second insulating layer INS2 and the third insulating layer INS3 to each other.

The opening OPA may be a single opening. In other words, the inorganic insulating layer NOINS may be directly adjacent to (e.g., touching) the passivation layer PVX through a single touching area in the peripheral area PA.

Because an area where the inorganic insulating layer NOINS is directly adjacent to (e.g., touching) the passivation layer PVX is formed, water and/or foreign substances can be prevented (or mitigated) from being drawn into the display area DA. Referring to FIGS. 1 and 4, the area (hereinafter, referred to as an inorganic area (e.g., inorganic touching area)) where the inorganic insulating layer NOINS and the passivation layer PVX are directly adjacent to (e.g., touching) each other may be formed along at least a portion of the perimeter (e.g., the peripheral area PA) of the display device DD. In other words, the inorganic area (or inorganic touching area) may form a closed loop for the display device DD.

In the second depressed area DTA2, the first insulating layer INS1 may be disposed between the inorganic insulating layer NOINS and the via layer VIA. In one or more embodiments, the first insulating layer INS1 disposed in the peripheral area PA may be omitted. In other words, the first insulating layer INS1 may be disposed only in the display area DA.

The first capping layer CAP1 may be disposed on the inorganic insulating layer NOINS to cover the first and second dam structures DAM1 and DAM2, the separation bank SBNK, and the color conversion layer CCL.

The organic insulating layer OINS may be disposed on the first capping layer CAP1. The organic insulating layer OINS may be located in the first depressed area DTA1 and the second depressed area DTA2.

The second capping layer CAP2 may be disposed on an overall surface of the organic insulating layer OINS, and may include an inorganic material. The second capping layer CAP2 may prevent water from permeating the organic insulating layer OINS.

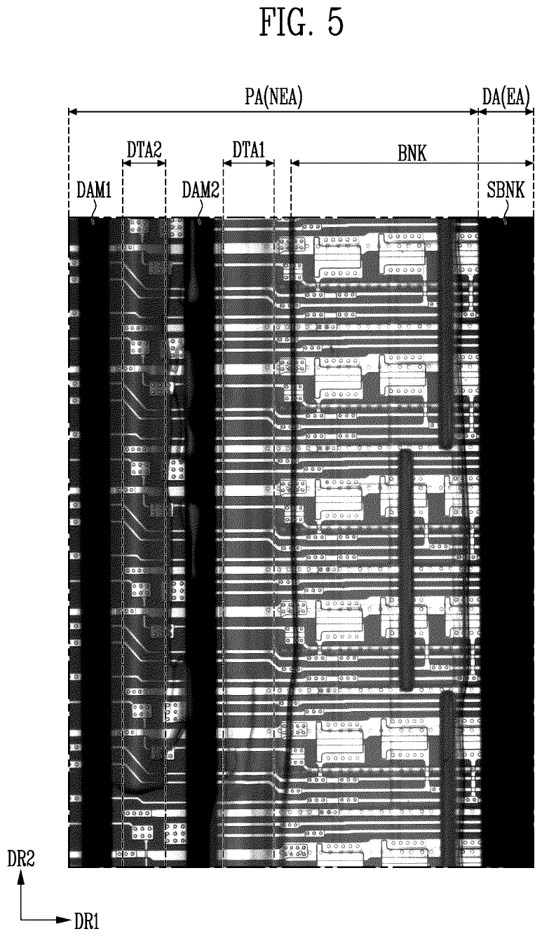

FIG. 5 is a plan view illustrating an embodiment of the peripheral area PA of the display device DD of FIG. 1. Although FIG. 5 illustrates a portion of a left side of the display device DD of FIG. 1, components applied to the left side of the display device DD may also be applied to a right side of the display device DD.

Referring to FIG. 5, the first and second dam structures DAM1 and DAM2 and the bank BNK may be spaced from each other and may be successively disposed along the first direction DR1.

The second depressed area DTA2 may be formed between the first dam structure DAM1 and the second dam structure DAM2. The first depressed area DTA1 may be formed between the second dam structure DAM2 and the bank BNK. The separation bank SBNK may be disposed on the bank BNK in the display area DA.

Referring to FIGS. 1 and 5, the first and second dam structures DAM1 and DAM2 may be disposed to extend along the perimeter of the display area DA. In one or more embodiments, based on the peripheral area PA disposed in each of a right side area and a left side area of the display device DD, the first and second dam structures DAM1 and DAM2 may extend in the second direction DR2. Based on the peripheral area PA disposed in each of an upper side area and a lower side area of the display device DD, the first and second dam structures DAM1 and DAM2 may extend in the first direction DR1.

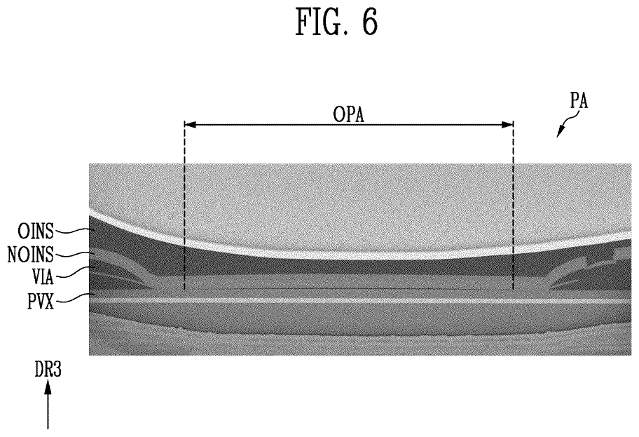

FIG. 6 is an enlarged view illustrating the passivation layer PVX and the inorganic insulating layer NOINS that are included in the peripheral area PA of FIG. 4.

The inorganic insulating layer NOINS may be directly adjacent to (e.g., touching) the passivation layer PVX through an opening OPA formed in the via layer VIA. In some cases, the inorganic insulating layer NOINS may come off in the opening OPA that is a single touching area. In this case, the inorganic insulating layer NOINS cannot prevent water or foreign substances from being drawn into the display area DA, and thus may cause a pixel (e.g., the pixel PXL of FIG. 3) disposed in the display area DA to be defective (e.g., occurrence of a non-emission pixel).

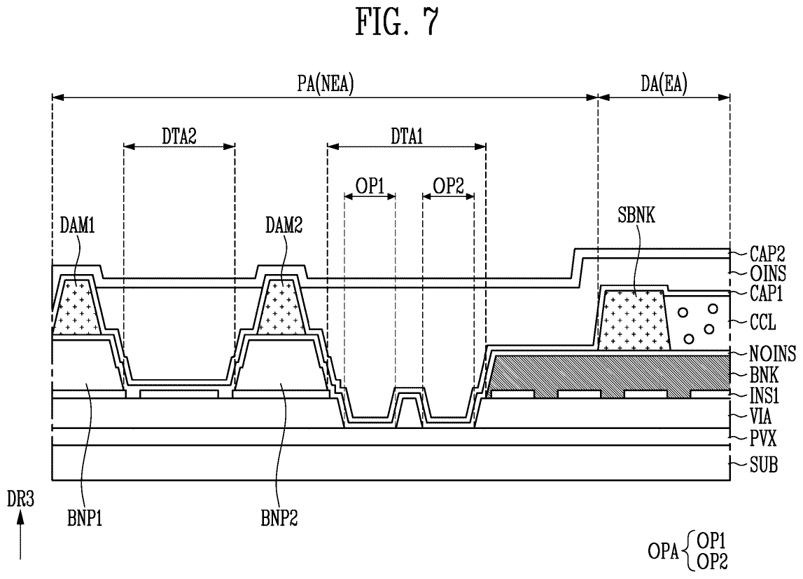

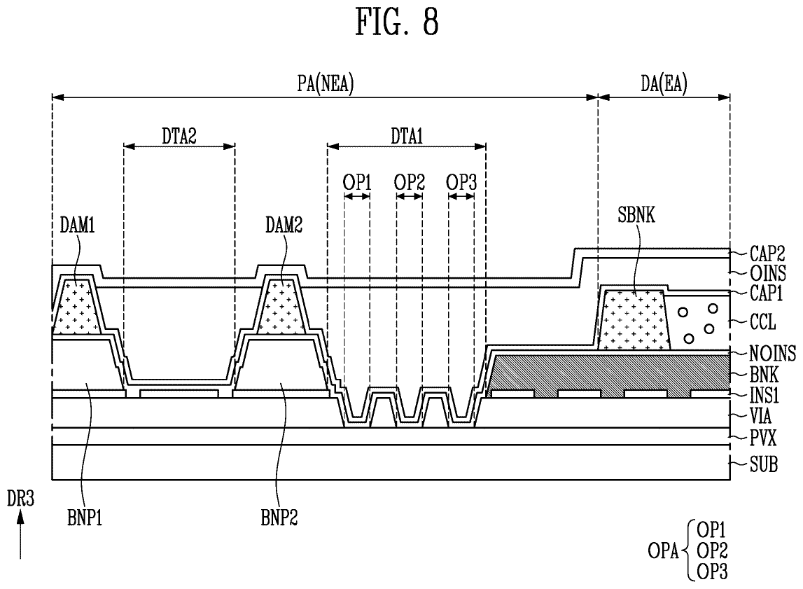

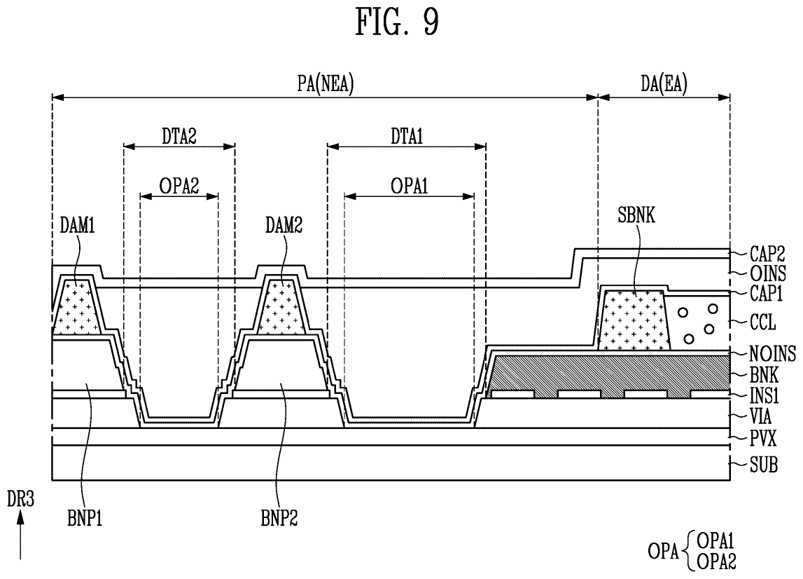

FIGS. 7 and 8 each are sectional views illustrating different embodiments of the peripheral area PA of the display device DD of FIG. 1. FIGS. 9 to 13 are sectional views illustrating different embodiments of the peripheral area PA of the display device DD of FIG. 1.

Referring to FIGS. 7 to 13, the via layer VIA disposed in the peripheral area PA may include at least two openings OPA. The inorganic insulating layer NOINS may be directly adjacent to (e.g., touching) the passivation layer PVX through the at least two openings OPA formed in the via layer VIA.

In the case where only a single touching area is present between the first dam structure DAM1 and the bank BNK, the inorganic insulating layer NOINS disposed in the single touching area may come off, or foreign substances or water may be drawn into the area where the inorganic insulating layer NOINS comes off. Consequently, a plurality of touching areas may be formed between the first dam structure DAM1 and the bank BNK so that even if the inorganic insulating layer NOINS disposed in one area of the plurality of touching areas comes off, the other touching areas can prevent inflow of foreign substances or water.

Referring to FIGS. 7 and 8, there are illustrated embodiments in which at least two openings OPA are disposed between the second dam structure DAM2 and the bank BNK. Referring to FIGS. 9 to 13, there are illustrated embodiments in which at least two openings OPA are disposed between the first dam structure DAM1 and the second dam structure DAM2 and between the second dam structure DAM2 and the bank BNK.

The following description with reference to the embodiments of FIGS. 7 to 13 will be focused on differences from the above-mentioned embodiments (e.g., the embodiment of FIG. 4) so as to avoid redundant description.

Referring to FIGS. 7 and 8, at least two openings OPA of the via layer VIA may be disposed between the second dam structure DAM2 and the bank BNK. In other words, at least two openings OPA of the via layer VIA may be disposed in an area that overlaps the first depressed area DTA1 formed by the second bank pattern BNP2 and the bank BNK.

In one or more embodiments, the via layer VIA disposed between the first dam structure DAM1 and the second dam structure DAM2 may overlap the passivation layer PVX in the third direction DR3.

Referring to FIG. 7, two apertures may be included in the first depressed area DTA1. In one or more embodiments, at least two openings OPA (OP1, OP2) may be included. A first aperture OP1 and a second aperture OP2 may be disposed in the first depressed area DTA1. The first aperture OP1 and the second aperture OP2 may be disposed to be spaced from each other. The inorganic insulating layer NOINS and the first capping layer CAP1 may be disposed on the via layer VIA to cover the first aperture OP1 and the second aperture OP2.

In one or more embodiments, the inorganic insulating layer NOINS may be directly adjacent to (e.g., touching) the passivation layer PVX through the first and second apertures OP1 and OP2. The inorganic insulating layer NOINS may be directly adjacent to (e.g., touching) the passivation layer PVX through the first and second apertures OP1 and OP2, which are a plurality of areas.

Referring to FIG. 8, three apertures may be included in the first depressed area DTA1. The at least two openings OPA may include a first aperture OP1, a second aperture OP2, and a third aperture OP3. The first aperture OP1, the second aperture OP2, and the third aperture OP3 may be disposed to be spaced from each other in one direction in the first depressed area DTA1.

Although a come-off phenomenon of the inorganic insulating layer NOINS may be mitigated as the number of areas where the inorganic insulating layer NOINS and the passivation layer PVX are adjacent to (e.g., touching) each other is increased, the number of apertures included in the via layer VIA in the first depressed area DTA1 may be determined, taking into account a width of the peripheral area PA and a minimum surface area of an area where the inorganic insulating layer NOINS and the passivation layer PVX are directly adjacent to (e.g., touching) each other.

In one or more embodiments, the inorganic insulating layer NOINS may be directly adjacent to (e.g., touching) the passivation layer PVX through the first, second, and third apertures OP1, OP2, and OP3. The inorganic insulating layer NOINS may be directly adjacent to (e.g., touching) the passivation layer PVX through the first, second, and third apertures OP1, OP2, and OP3 that are a plurality of areas.

Although FIG. 8 illustrates that the at least two openings OPA include three apertures, the present disclosure is not limited thereto. For example, the at least two openings OPA may include four or more apertures.

Referring to FIGS. 9 to 13, the at least two openings OPA may include a first opening OPA1 and a second opening OPA2. The first opening OPA1 and the second opening OPA2 may be disposed to be spaced from each other based on the second dam structure DAM2 (or with the second dam structure DAM2 interposed therebetween). The first opening OPA1 may be disposed between the second dam structure DAM2 and the bank BNK (or in the first depressed area DTA1). The second opening OPA2 may be disposed in an area (or the second depressed area DTA2) between the first dam structure DAM1 and the second dam structure DAM2.

As a touching area (or the second opening OPA2) is further formed between the first dam structure DAM1 and the second dam structure DAM2, there is increased probability that the inorganic insulating layer OINS can prevent foreign substances and/or water from being drawn into the display area DA.

The first opening OPA1 may be disposed between the second dam structure DAM2 and the bank BNK. The second opening OPA2 may be disposed between the first dam structure DAM1 and the second dam structure DAM2. The inorganic insulating layer NOINS and the first capping layer CAP1 may be disposed on the via layer VIA to cover the first opening OPA1 and the second opening OPA2. The inorganic insulating layer NOINS may be directly adjacent to (e.g., touching) the passivation layer PVX through the first and second openings OPA1 and OPA2. The inorganic insulating layer NOINS may be directly adjacent to (e.g., touching) the passivation layer PVX through the first and second openings OPA1 and OPA2, which are a plurality of areas.

In one or more embodiments, at least one aperture may be included in each of the first depressed area DTA1 and the second depressed area DTA2. In one or more embodiments, the first opening OPA1 may include at least two or more apertures, and the second opening OPA2 may include one aperture, but the present disclosure is not limited thereto.

The via layer VIA may include not only the first opening OPA1 formed between the bank BNK and the second dam structure DAM2 adjacent to the display area DA but also the second opening OPA2 formed between the first dam structure DAM1 and the second dam structure DAM2. Hence, the area where the inorganic insulating layer NOINS and the passivation layer PVX are adjacent to (e.g., touching) each other can be increased in the peripheral area PA of the display device, so that water or foreign substances can be more effectively prevented from being drawn into the display area DA.

Referring to FIG. 9, the at least two openings of the via layer VIA may include the first opening OPA1 and the second opening OPA2. Each of the first opening OPA1 and the second opening OPA2 may include one aperture.

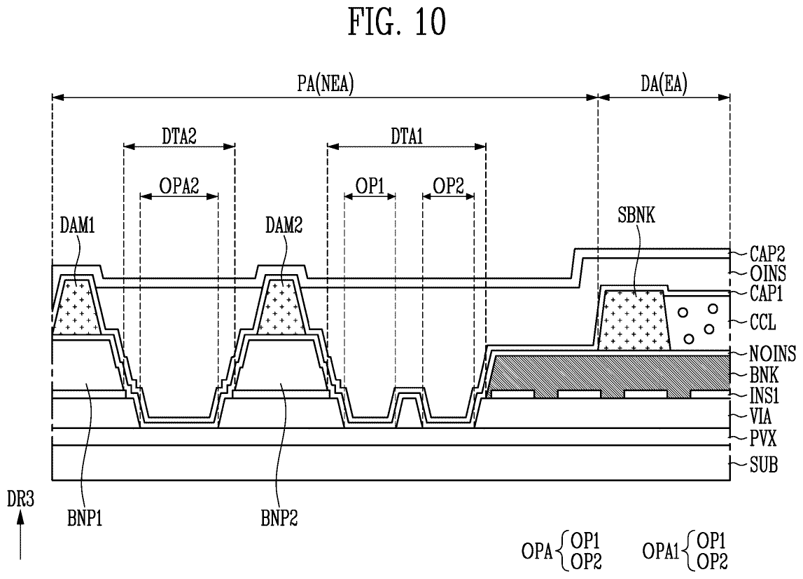

Referring to FIG. 10, the at least two openings of the via layer VIA may include the first opening OPA1 and the second opening OPA2. The first opening OPA1 may include two apertures OP1 and OP2. The second opening OPA2 may include one aperture.

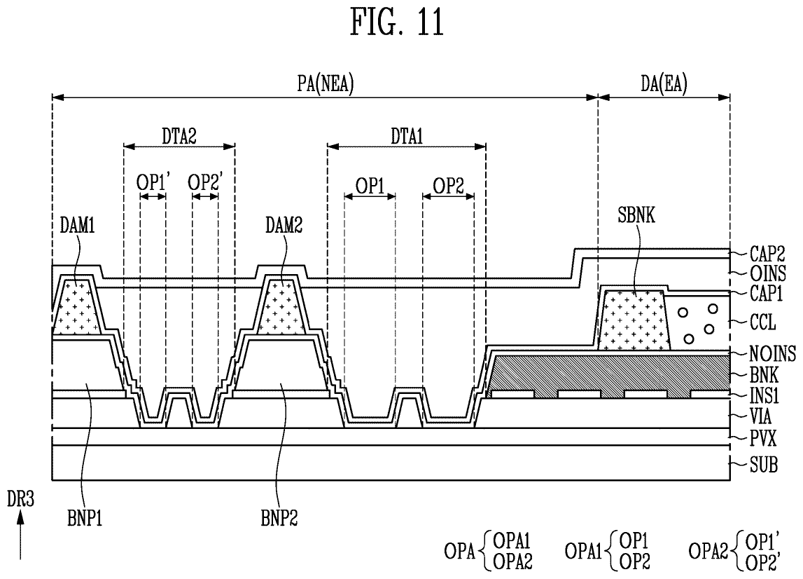

Referring to FIG. 11, the at least two openings of the via layer VIA may include the first opening OPA1 and the second opening OPA2. Each of the first opening OPA1 and the second opening OPA2 may include two apertures. The first opening OPA1 may include first and second apertures OP1 and OP2. The second opening OPA2 may include first and second apertures OP1′ and OP2′.

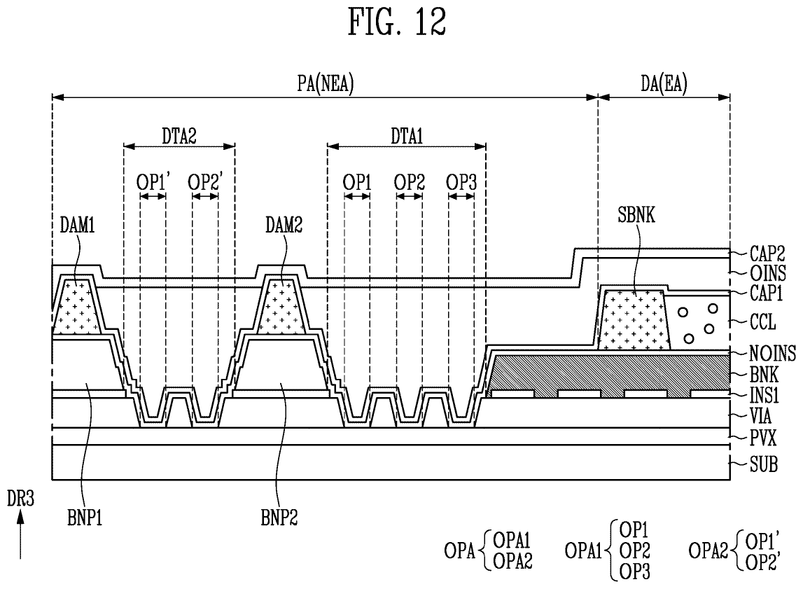

Referring to FIG. 12, the at least two openings of the via layer VIA may include the first opening OPA1 and the second opening OPA2. The first opening OPA1 may include three apertures. The second opening OPA2 may include two apertures. The first opening OPA1 may include first, second, and third apertures OP1, OP2, and OP3. The second opening OPA2 may include first and second apertures OP1′ and OP2′.

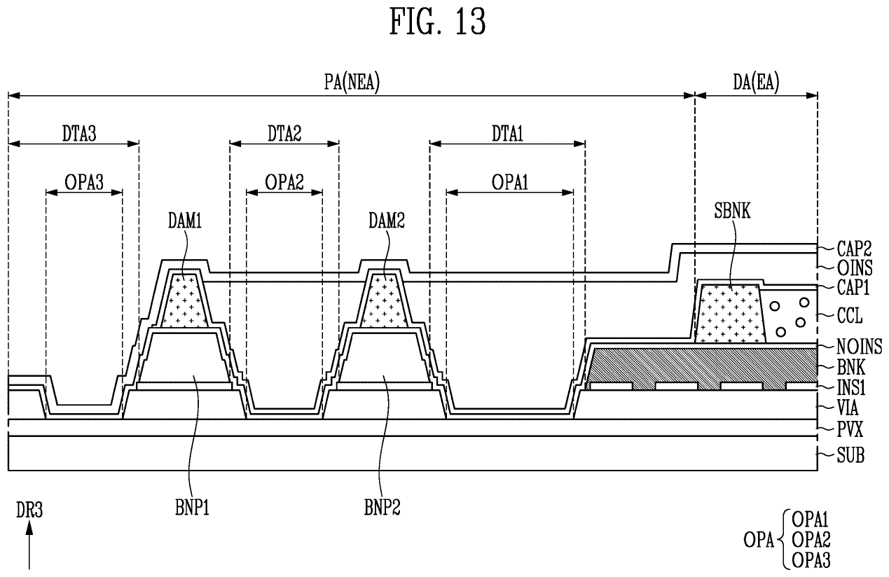

Referring to FIG. 13, the peripheral area PA may further include a third depressed area DTA3. The third depressed area DTA3 may be one area in which the organic insulating layer OINS is not disposed, based on the first dam structure DAM1 (or between the first dam structure DAM1 and the perimeter of the display device DD). The first and second depressed areas DTA1 and DTA2 each may be an area in which the organic insulating layer OINS is disposed.

In one or more embodiments, the third depressed area DTA3 may be an area adjacent to the perimeter of the display device (e.g., the display device DD of FIG. 1). The substrate SUB, the passivation layer PVX, the via layer VIA, and the inorganic insulating layer NOINS may be disposed to extend to the third depressed area DTA3.

The via layer VIA disposed in the third depressed area DTA3 may include a third opening OPA3. The inorganic insulating layer NOINS and the second capping layer CAP2 may be disposed on the via layer VIA to cover the third opening OPA3.

In one or more embodiments, the third opening OPA3 may include at least one aperture.

In one or more embodiments, the inorganic insulating layer NOINS may be directly adjacent to (e.g., touching) the passivation layer PVX through the third opening OPA3. The inorganic insulating layer NOINS may be directly adjacent to (e.g., touching) the passivation layer PVX through the first, second, and third openings OPA1, OPA2, and OPA3 that are a plurality of areas.

The via layer VIA may further include a third opening OPA3 in a direction toward a perimeter area of the peripheral area PA, as well as including the first and second openings OPA1 and OPA2. Consequently, the area where the inorganic insulating layer NOINS and the passivation layer PVX are adjacent to (e.g., touching) each other in the peripheral area PA of the display device may be increased, so that water or foreign substances can be more effectively prevented (mitigated) from being drawn into the display area DA.

In the display device in accordance with one or more embodiments of the present disclosure, the inorganic touching area that is disposed in the peripheral area between the inorganic insulating layer NOINS and the passivation layer PVX to prevent water and/or foreign substances from being drawn into the display area may be increased. As the inorganic touching area is increased, a come-off phenomenon of the inorganic insulating layer NOINS can be prevented from occurring, so that the durability of the inorganic insulating layer can be secured. Therefore, the inorganic insulating layer may more effectively prevent water and/or foreign substances from being drawn into the display area.

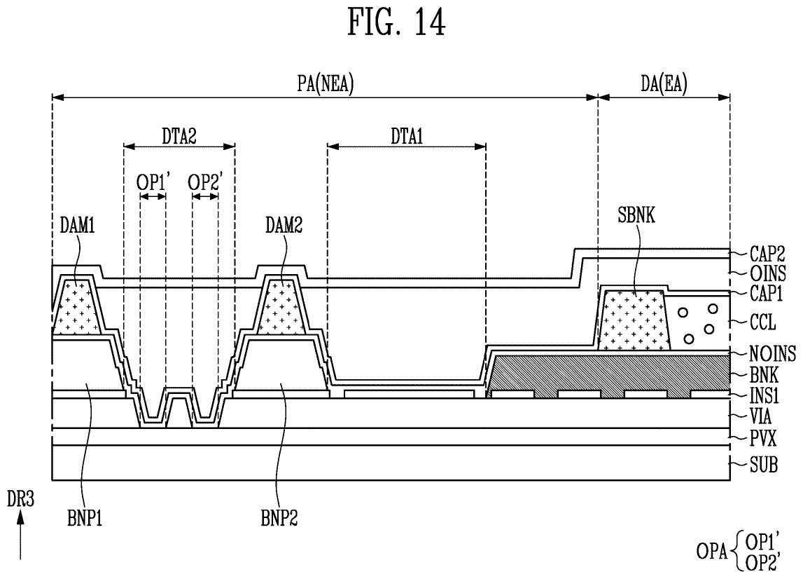

FIG. 14 is a sectional view illustrating an embodiment of the peripheral area PA of the display device DD of FIG. 1.

The following description with reference to the embodiment of FIG. 14 will be focused on differences from the above-mentioned embodiments (e.g., the embodiments of FIGS. 7 to 13) so as to avoid redundant description.

Referring to FIG. 14, the via layer VIA that is disposed in the peripheral area PA may include at least one opening OPA. The at least one opening OPA may be disposed between the first dam structure DAM1 and the second dam structure DAM2. The via layer VIA disposed between the second dam structure DAM2 and the bank BNK may not have an opening. In other words, the via layer VIA disposed between the second dam structure DAM2 and the bank BNK may overlap the passivation layer PVX in the third direction DR3.

In one or more embodiments, the at least one opening OPA may include a first aperture OP1′ and a second aperture OP2′. The first aperture OP1′ and the second aperture OP2′ may be disposed to be spaced from each other. The inorganic insulating layer NOINS and the first capping layer CAP1 may be disposed on the via layer VIA to cover the first aperture OP1′ and the second aperture OP2′.

In one or more embodiments, the inorganic insulating layer NOINS may be directly adjacent to (e.g., touching) to the passivation layer PVX through the first and second apertures OP1′ and OP2′. The inorganic insulating layer NOINS may be directly adjacent to (e.g., touching) to the passivation layer PVX through the first and second apertures OP1′ and OP2′, which are a plurality of areas.

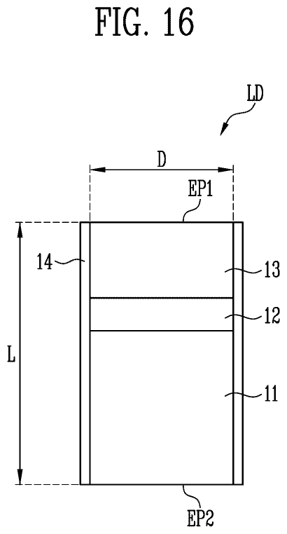

FIGS. 15 and 16 are diagrams each illustrating a light emitting element in accordance with one or more embodiments.

Referring to FIGS. 15 and 16, the light emitting element LD may include a first semiconductor layer 11, a second semiconductor layer 13, and an active layer 12 interposed between the first and second semiconductor layers 11 and 13. For example, the light emitting element LD may be implemented as an emission stack (or referred to as “stacked pattern”) formed by successively stacking the first semiconductor layer 11, the active layer 12, and the second semiconductor layer 13.

The light emitting element LD may be formed in a shape extending in one direction. If the direction in which the light emitting element LD extends is defined as a longitudinal direction, the light emitting element LD may have a first end EP1 and a second end EP2 with respect to the longitudinal direction. One semiconductor layer of the first semiconductor layer 11 and the second semiconductor layer 13 may be disposed on the first end EP1 of the light emitting element LD, and the other semiconductor layer of the first semiconductor layer 11 and the second semiconductor layer 13 may be disposed on the second end EP2 of the light emitting element LD.

The light emitting element LD may be provided in various shapes. For example, as illustrated in FIG. 13, the light emitting element LD may have a rod-like shape, a bar-like shape, or a pillar-like shape that is long with respect to the longitudinal direction (i.e., to have an aspect ratio greater than 1). Alternatively, the light emitting element LD may have a rod-like shape, a bar-like shape, or a pillar-like shape that is short with respect to the longitudinal direction (or has an aspect ratio less than 1). As a further alternative, the light emitting element LD may have a rod-like shape, a bar-like shape, or a pillar-like shape having an aspect ratio of 1.

The light emitting element LD may include a light emitting diode (LED) fabricated to have a subminiature size, e.g., with a diameter D and/or a length L corresponding to a range from the nano scale (or the nanometer scale) to the micro scale (or the micrometer scale).

In case that the light emitting element LD is long (i.e., to have an aspect ratio greater than 1) with respect to the longitudinal direction, the diameter D of the light emitting element LD may approximately range from 0.5 μm to 6 μm, and the length L thereof may approximately range from 1 μm to 10 μm. However, the diameter D and the length L of the light emitting element LD are not limited thereto. The size of the light emitting element LD may be changed to meet requirements (or design conditions) of a lighting device or a self-emissive display device to which the light emitting element LD is applied.

The first semiconductor layer 11 may include, for example, at least one n-type semiconductor layer. The first semiconductor layer 11 may include, with respect to the longitudinal direction of the light emitting element LD, an upper surface that contacts the active layer 12, and a lower surface exposed to the outside. The lower surface of the first semiconductor layer 11 may correspond to one end (or a lower end) of the light emitting element LD.

The active layer 12 may be disposed on the first semiconductor layer 11 and have a single- or multi-quantum well structure. For example, in case that the active layer 12 is formed to have a multi-quantum well structure, the active layer 12 may be formed by periodically repeatedly stacking a barrier layer, a stain reinforcing layer, and a well layer that are provided as one unit. The stain reinforcing layer may have a lattice constant less than that of the barrier layer so that resistance to strain, e.g., compressive strain, to be applied to the well layer can be further reinforced. However, the structure of the active layer 12 is not limited to that of the foregoing embodiment.

The active layer 12 may emit light having a wavelength approximately ranging from 400 nm to 900 nm, and have a double hetero structure. The active layer 12 may include a first surface that contacts the first semiconductor layer 11, and a second surface that contacts the second semiconductor layer 13.

Depending on the wavelength of light emitted from the active layer 12, the color (or output light color) of the light emitting element LD may be determined. The color of the light emitting element LD may determine the color of the corresponding pixel. For example, the light emitting element LD may emit red light, green light, or blue light.

If an electric field having a certain voltage or more is applied between the opposite ends of the light emitting element LD, the light emitting element LD may emit light by coupling of electron-hole pairs in the active layer 12. Because light emission of the light emitting element LD can be controlled based on the foregoing principle, the light emitting element LD may be used as a light source (a light emitting source) of various light emitting devices as well as a pixel of a display device.

The second semiconductor layer 13 may be disposed on the second surface of the active layer 12 and include a semiconductor layer of a type different from that of the first semiconductor layer 11. For example, the second semiconductor layer 13 may include at least one p-type semiconductor layer.

The second semiconductor layer 13 may include, with regard to the longitudinal direction of the light emitting element LD, a lower surface that contacts the second surface of the active layer 12, and an upper surface exposed to the outside. Here, the upper surface of the second semiconductor layer 13 may correspond to a remaining end (or an upper end) of the light emitting element LD.

The first semiconductor layer 11 and the second semiconductor layer 13 may have different thicknesses with respect to the longitudinal direction of the light emitting element LD. For example, the first semiconductor layer 11 may have a thickness greater than that of the second semiconductor layer 13 with respect to the longitudinal direction of the light emitting element LD. Hence, the active layer 12 of the light emitting element LD may be disposed at a position closer to the upper surface of the second semiconductor layer 13 than to the lower surface of the first semiconductor layer 11.

Although the first semiconductor layer 11 and the second semiconductor layer 13 each are formed of a single layer, the present disclosure is not limited thereto. In one or more embodiments, depending on the material of the active layer 12, the first semiconductor layer 11 and the second semiconductor layer 13 each may further include one or more layers, for example, a clad layer and/or a tensile strain barrier reducing (TSBR) layer. The TSBR layer may be a strain relief layer that is disposed between semiconductor layers having different lattice structures and thus can function as a buffer layer to reduce a difference in lattice constant. Although the TSBR layer may be formed of a p-type semiconductor layer such as p-GaInP, p-AlInP, or p-AlGaInP, the present disclosure is not limited thereto.

The light emitting element LD may further include a contact electrode (hereinafter referred to as “first contact electrode”) disposed over the second semiconductor layer 13, as well as including the first semiconductor layer 11, the active layer 12, and the second semiconductor layer 13. Furthermore, in one or more embodiments, the light emitting element LD may further include an additional contact electrode (hereinafter referred to as “second contact electrode”) disposed on one end of the first semiconductor layer 11.

Each of the first and second contact electrodes may be an ohmic contact electrode, but the present disclosure is not limited thereto. In one or more embodiments, each of the first and second contact electrodes may be a Schottky contact electrode. The first and second contact electrodes may include a conductive material.

The light emitting element LD may further include an insulating layer 14 (or referred to as “insulating film”). However, in one or more embodiments, the insulating layer 14 may be omitted, or may be provided to cover only some of the first semiconductor layer 11, the active layer 12, and the second semiconductor layer 13.

The insulating layer 14 may prevent the active layer 12 from short-circuiting due to making contact with the conductive material except the first and second semiconductor layers 11 and 13. Furthermore, the insulating layer 14 may reduce or minimize a surface defect of the light emitting element LD, thus enhancing the lifetime and emission efficiency of the light emitting element LD. The presence or non-presence of the insulating layer 14 is not limited, so long as the active layer 12 can be prevented from short-circuiting with an external conductive material.

The insulating layer 14 may be provided to be around (e.g., to enclose) at least a portion of an outer surface (e.g., an outer peripheral or circumferential surface) of the emission stack including the first semiconductor layer 11, the active layer 12, and the second semiconductor layer 13.

Although in the foregoing embodiment the insulating layer 14 has been described as enclosing the entirety of the outer surface (e.g., the outer peripheral or circumferential surface) of each of the first semiconductor layer 11, the active layer 12, and the second semiconductor layer 13, the present disclosure is not limited thereto.

The insulating layer 14 may include a transparent insulating material. For example, the insulating layer 14 may include one or more insulating materials selected from the group of silicon oxide (SiOₓ), silicon nitride (SiNₓ), silicon oxynitride (SiOₓN_{y}), aluminum oxide (AlOₓ), titanium oxide (TiOₓ), hafnium oxide (HfOₓ), titanstrontium oxide (SrTiOₓ), cobalt oxide (CoₓO_{y}), magnesium oxide (MgO), zinc oxide (ZnOₓ), ruthenium Oxide (RuOₓ), nickel oxide (NiO), tungsten oxide (WOₓ), tantalum oxide (TaOₓ), gadolinium oxide (GdOₓ), zirconium oxide (ZrOₓ), gallium oxide (GaOₓ), vanadium oxide (VₓO_{y}), ZnO:Al, ZnO:B, InxOy:H, niobium oxide (NbₓO_{y}), magnesium fluoride (MgFₓ), aluminum fluoride (AlFₓ), an alucone polymer film, titanium nitride (TiN), tantalum nitride (TaN), aluminum nitride (AlNₓ), gallium nitride (GaN), tungsten nitride (WN), hafnium nitride (HfN), niobium nitride (NbN), gadolinium nitride (GdN), zirconium nitride (ZrN), and/or vanadium nitride (VN). However, the present disclosure is not limited thereto, and various materials having insulation may be used as the material of the insulating layer 14.

The insulating layer 14 may have a single-layer structure or a multi-layer structure including a double-layer structure.

The light emitting element LD may be employed as a light emitting source (or a light source) for various display devices. The light emitting element LD may be fabricated through a surface treatment process. For example, the light emitting element LD may be surface-treated so that, when a plurality of light emitting elements LD are mixed with a fluidic solution (or solvent) and then supplied to each pixel area (e.g., an emission area of each pixel or an emission area of each sub-pixel), the light emitting elements LD can be evenly distributed rather than unevenly aggregating in the solution.

An emission component (or a light emitting device) including the light emitting elements LD described above may be used not only in a display device but also in various types of electronic devices each of which requires a light source. For instance, in the case where a plurality of light emitting elements LD are disposed in the pixel area of each pixel of a display panel, the light emitting elements LD may be used as a light source of the pixel. However, the application field of the light emitting element LD is not limited to the above-mentioned examples. For example, the light emitting element LD may also be used in other types of electronic devices such as a lighting device, which requires a light source.

However, the foregoing is only for illustrative purposes, and the light emitting element LD in accordance with one or more embodiments of the present disclosure is not limited thereto. For example, the light emitting element may be a flip chip type micro light emitting diode, or an organic light emitting element including an organic emission layer.

In a display device in accordance with one or more embodiments of the present disclosure, a plurality of directly adjacent areas (e.g., touching areas) between inorganic layers may be included in a peripheral area disposed on one side of the display area, so that the durability of the inorganic layer can be secured. Consequently, the inorganic layers may more effectively prevent (or mitigate) water and/or foreign substances from being drawn into the display area.

In the display device, occurrence of a defect in a pixel in the display area attributable to water and/or foreign substances drawn into the display area may be mitigated.

However, effects, aspects, and features of the present disclosure are not limited to the above-described effects, aspects, and features, and various modifications are possible without departing from the spirit and scope of the present disclosure.

While embodiments of the present disclosure have been described above, those skilled in the art will appreciate that various modifications, additions and substitutions are possible, without departing from the scope and spirit of the present disclosure claimed in the appended claims.

What is claimed is:

1. A display device comprising:
a substrate including a display area and a peripheral area located on one side of the display area;
a first inorganic layer on the substrate;
a first organic layer on the first inorganic layer;
a light emitting element on the first organic layer in the display area;
a second inorganic layer on the first organic layer and the light emitting element;
a second organic layer on the second inorganic layer;
a color conversion layer on the second inorganic layer in the display area, and configured to convert a wavelength of light emitted from the light emitting element;
a third inorganic layer on the second inorganic layer and the color conversion layer; and
a first dam structure on the second inorganic layer in the peripheral area,
wherein the first organic layer includes at least two openings between the first dam structure and the display area,
wherein the second inorganic layer directly contacts the first inorganic layer through the at least two openings, and
wherein the third inorganic layer directly contacts the second inorganic layer in the at least two openings.

2. The display device according to claim 1, further comprising a transistor on the substrate,
wherein the first insulating layer is on the first transistor.

3. The display device according to claim 1, further comprising a second dam structure on the first organic layer in the peripheral area, and located between the first dam structure and the display area.

4. The display device according to claim 3, wherein the at least two openings of the first organic layer are between the second dam structure and the display area.

5. The display device according to claim 4, wherein the first organic layer between the first dam structure and the second dam structure does not include an opening.

6. The display device according to claim 3, wherein the first organic layer between the first dam structure and the display area includes a first opening and a second opening that is spaced from the first opening.

7. The display device according to claim 6, wherein the first opening and the second opening are located between the second dam structure and the display area.

8. The display device according to claim 6, wherein the first opening is between the second dam structure and the display area, and the second opening is between the first dam structure and the second dam structure.

9. The display device according to claim 3, wherein the first organic layer between the first dam structure and the display area includes a first opening, a second opening, and a third opening that are spaced from each other.

10. The display device according to claim 9, wherein the first opening, the second opening, and the third opening are between the second dam structure and the display area.

11. The display device according to claim 9,
wherein the first opening and the second opening are between the second dam structure and the display area, and
wherein the third opening is between the first dam structure and the second dam structure.

12. The display device according to claim 3,
wherein the first organic layer between the first dam structure and the display area includes a first opening, a second opening, a third opening, and a fourth opening that are spaced from each other,
wherein the first opening and the second opening are between the second dam structure and the display area, and
wherein the third opening and the fourth opening are between the first dam structure and the second dam structure.

13. The display device according to claim 3,
wherein the first organic layer between the first dam structure and the display area includes a first opening, a second opening, a third opening, a fourth opening, and a fifth opening that are spaced from each other,
wherein the first opening, the second opening, and the third opening are between the second dam structure and the display area, and
wherein the fourth opening and the fifth opening are between the first dam structure and the second dam structure.

14. The display device according to claim 3, wherein the first organic layer further includes at least one opening between the first dam structure and a perimeter of the display device.

15. The display device according to claim 14, wherein the second organic layer is on the third organic layer,
the display device further comprising a fourth inorganic layer on the second organic layer and configured to cover the display area and the peripheral area, and
wherein the fourth inorganic layer directly contacts the third inorganic layer in the peripheral area.

16. The display device according to claim 1, further comprising:
a first bank on the first organic layer in the display area; and
a first bank pattern on the first organic layer in the peripheral area,
wherein the first dam structure is on the first bank pattern, and
wherein the second insulating layer covers the first bank and the first bank pattern.

17. The display device according to claim 16,
wherein the color conversion layer further includes a second bank overlapping the first bank in a plan view, and
wherein the first dam structure is at a same layer as the second bank.

18. A display device comprising:
a substrate including a display area and a peripheral area located on at least one side of the display area;
a first inorganic layer on the substrate;
a first organic layer on the first inorganic layer;
a light emitting element on the first organic layer in the display area;
a second inorganic layer on the first organic layer and the light emitting element; and
a first dam structure and a second dam structure in the peripheral area,
wherein the first organic layer includes at least two openings between the first dam structure and the second dam structure, and
wherein the second inorganic layer directly contacts the first inorganic layer through the at least two openings.

19. The display device according to claim 18, wherein the first organic layer between the second dam structure and the display area does not include an opening.

20. The display device according to claim 18, further comprising a transistor on the substrate,
wherein the first insulating layer is on the transistor.
